(19) United States
(12) Patent Application Publication
(10) Pub. No.: US 2024/0321721 A1
(43) Pub. Date: Sep. 26, 2024

(54) STRETCHABLE DEVICE

(71) Applicant: Murata Manufacturing Co., Ltd., Nagaokakyo-shi (JP)

(72) Inventors: Keisuke NISHIDA, Nagaokakyo-shi (JP); Yui NAKAMURA, Nagaokakyo-shi (JP); Nobuyasu HORI, Nagaokakyo-shi (JP)

(21) Appl. No.: 18/734,031

(22) Filed: Jun. 5, 2024

Related U.S. Application Data
(63) Continuation of application No. PCT/JP2022/042423, filed on Nov. 15, 2022.

(30) Foreign Application Priority Data
Dec. 10, 2021 (JP) 2021-201035

(51) Int. Cl. H01L 23/498

(52) U.S. Cl. CPC H01L 23/4985; H01L 23/49838; H01L 23/49822

(57) ABSTRACT

A stretchable device that includes: a first substrate having a first main surface and a second main surface facing each other; a first wiring on the first main surface and extending along the first main surface; a second wiring adjacent to the first wiring; a second stretchable substrate having a third main surface and a fourth main surface facing each other, the second stretchable substrate connected to the first stretchable substrate; a stretchable third wiring on the fourth main surface and extending along the fourth main surface; and a stretchable fourth wiring adjacent to the third wiring, wherein a shortest distance between the first wiring and the second wiring is shorter than a shortest distance between the third wiring and the fourth wiring.

### CROSS REFERENCE TO RELATED APPLICATIONS

The present application is a continuation of International application No. PCT/JP2022/042423, filed Nov. 15, 2022, which claims priority to Japanese Patent Application No. 2021-201035, filed Dec. 10, 2021, the entire contents of each of which are incorporated herein by reference.

### TECHNICAL FIELD

The present disclosure relates to a stretchable device.

### BACKGROUND ART

Conventionally, as a stretchable device, there is one described in Japanese Patent Application Laid-Open No. 2017-118109 (Patent Document 1). The stretchable device includes one stretchable substrate and a stretchable wiring formed on one main surface of the stretchable substrate.
Patent Document 1: Japanese Patent Application Laid-Open No. 2017-118109

### SUMMARY OF THE DISCLOSURE

In a stretchable device, there are a region where wiring density is high and a region where wiring density is low. At the time of manufacturing a stretchable device, in a region where wiring density is high, difficulty of laying a stretchable wiring on a stretchable substrate is high. Therefore, when an attempt is made to manufacture a stretchable device using one stretchable substrate, there is a problem that, in a case where a defect occurs in a portion with high degree of manufacturing difficulty, the entire stretchable device becomes defective, and yield is lowered. Further, when an attempt is made to increase accuracy at the time of manufacturing in accordance with a portion with a high degree of difficulty at the time of manufacturing, there is also a problem that manufacturing efficiency is lowered, and as a result, yield decreases.

In view of the above, an object of the present disclosure is to provide a stretchable device having a low degree of difficulty at the time of manufacturing that can be manufactured with high yield.

In order to solve the above problem, a stretchable device according to an aspect of the present disclosure includes: a first substrate having a first main surface and a second main surface facing each other; a first wiring on the first main surface and extending along the first main surface; a second wiring adjacent to the first wiring; a second stretchable substrate having a third main surface and a fourth main surface facing each other, the second stretchable substrate connected to the first stretchable substrate; a stretchable third wiring on the fourth main surface and extending along the fourth main surface; and a stretchable fourth wiring adjacent to the third wiring, wherein a shortest distance between the first wiring and the second wiring is shorter than a shortest distance between the third wiring and the fourth wiring.

Here, “on the main surface” refers not to an absolute direction such as vertical direction defined in the direction of gravity but to a direction toward the outside between the outside and the inside of the substrate having the main surface as a boundary. Therefore, “on the main surface” is a relative direction determined by orientation of the main surface. Further, “on” a certain element includes not only a position immediately above and in contact with the element (on) but also an upper position away from the element, that is, an upper position with another object on the element interposed between them or an upper position with a space between them (above).

According to the above aspect, arrangement is made so that a shortest distance between the first wiring and the second wiring provided on the first substrate is shorter than a shortest distance between the third wiring and the fourth wiring that are stretchable provided on the second substrate that is stretchable. For this reason, while a fine wiring pattern having a high degree of difficulty at the time of manufacturing is formed on the first substrate, wirings are arranged on the stretchable second substrate in a relatively sparsely dispersed manner. Therefore, degree of manufacturing difficulty is not high, and the manufacturing can be performed with high yield.

Further, preferably, in one embodiment of the stretchable device, a shortest distance between the first wiring and the second wiring is less than 250 μm, and a shortest distance between the third wiring and the fourth wiring is 250 μm or more.

According to the above embodiment, since a distance between the wirings provided on the first substrate is less than 250 μm and a distance between the wirings provided on the second substrate is 250 μm or more, it is easy to adjust a difference in degree of manufacturing difficulty according to a type of substrate, and it is easy to lower degree of manufacturing difficulty of the stretchable device and manufacture the stretchable device with higher yield.

Preferably, one embodiment of the stretchable device further includes a first electronic component only on the first main surface, and the first electronic component is electrically connected to the first wiring and the second wiring.

According to the above embodiment, since the electronic component is provided only on the first substrate, it is easy to lower degree of manufacturing difficulty of the second substrate and to manufacture the second substrate with high yield.

Preferably, one embodiment of the stretchable device further includes a first electronic component provided on the first main surface, and a second electronic component provided on the fourth main surface, and the first electronic component includes a first terminal electrically connected to the first wiring and a second terminal electrically connected to the second wiring, the second electronic component includes a third terminal electrically connected to the third wiring and a fourth terminal electrically connected to the fourth wiring, and a shortest distance between the first terminal and the second terminal is shorter than a shortest distance between the third terminal and the fourth terminal.

According to the above embodiment, in a case where the second electronic component is also provided on the second substrate that is stretchable, a shortest distance between the first terminal and the second terminal in the first electronic component on the first substrate is shorter than a shortest distance between the third terminal and the fourth terminal in the second electronic component on the second substrate. For this reason, it is easy to lower degree of manufacturing difficulty of the second substrate and to manufacture the second substrate with high yield.

Preferably, one embodiment of the stretchable device further includes a fifth wiring provided on the first main surface, and the fifth wiring has a region overlapping the first wiring or the second wiring when viewed from a direction orthogonal to the first main surface.

According to the above embodiment, the wiring having a more complicated structure is arranged on the first substrate, and a structure of the wiring in the second substrate can be simplified. For this reason, it is easy to lower degree of manufacturing difficulty of the second substrate and to manufacture the second substrate with high yield.

Preferably, one embodiment of the stretchable device further includes a conductive member that electrically connects the first wiring and the third wiring.

According to the above embodiment, since the first wiring and the third wiring are electrically connected via the conductive member, connection reliability can be enhanced. Further, since it is not necessary to directly join the first wiring and the third wiring, degree of manufacturing difficulty can be lowered.

Preferably, in one embodiment of the stretchable device, the first substrate and the second substrate are arranged such that the first main surface and the fourth main surface face each other, the first wiring and the third wiring are arranged to face each other in a direction orthogonal to the first main surface, and the conductive member is arranged between a first wiring and a third wiring.

According to the above embodiment, connection reliability between the first wiring and the third wiring can be further enhanced. Furthermore, since the first substrate and the second substrate may be connected by the conductive member, mechanical strength of a joint portion between the first substrate and the second substrate can be increased.

Preferably, in an embodiment of the stretchable device, the conductive member contains a conductive particle, and particle size of the conductive particle is larger than a distance between the first wiring and the third wiring.

According to the above embodiment, since particle size of the conductive particle having conductivity is larger than a distance between the first wiring and the third wiring electrically connected, the first wiring and the third wiring are more reliably electrically connected.

Preferably, in one embodiment of the stretchable device, in a section orthogonal to a direction in which the first wiring extends in a portion where the conductive member, the first wiring, and the third wiring overlap, width of the first wiring and width of the third wiring are different.

According to the above embodiment, since width of the first wiring and width of the second wiring are different at a portion where the first wiring and the third wiring overlap, doming is prevented, and the first wiring and the third wiring can be reliably electrically connected.

Preferably, in one embodiment of the stretchable device, in a section orthogonal to a direction in which the first wiring extends in a portion where the first wiring and the third wiring overlap, width of a narrower one of the first wiring and the third wiring is 500 μm or less.

According to the above embodiment, since width of a narrower one of the wirings is 500 μm or less at a portion where the first wiring and the third wiring overlap, doming is further prevented, and electrical connection between the first wiring and the third wiring is further improved.

Preferably, in one embodiment of the stretchable device, an end portion of at least one of the first wiring and the third wiring has a plurality of tooth portions provided in parallel and separately in a width direction.

According to the above embodiment, since at least one of the first wiring and the third wiring has a comb-tooth-shaped end portion, doming is prevented, and electrical connection between the first wiring and the third wiring is excellent.

Preferably, in one embodiment of the stretchable device, a distance between two adjacent ones of the tooth portions is 700 μm or less.

According to the above embodiment, since an interval between the tooth portions is 700 μm or less, the first wiring and the third wiring are more reliably electrically connected.

Preferably, in one embodiment of the stretchable device, distances between two adjacent ones of the tooth portions are all the same.

According to the above embodiment, since a plurality of the tooth portions are arranged at equal intervals in the width direction, the first wiring and the third wiring are more reliably electrically connected.

Preferably, in one embodiment of the stretchable device, a distance between two adjacent ones of the tooth portions is 200 μm or more.

According to the above embodiment, since an interval between a plurality of the tooth portions is 200 μm or more, doming is further prevented, and electrical connection between the first wiring line and the third wiring line is further improved.

Preferably, one embodiment of the stretchable device further includes: a first insulating coating layer coating the first wiring, and the first insulating coating layer overlaps the conductive member when viewed from a direction orthogonal to the first main surface.

According to the above embodiment, since the first wiring is covered with the first insulating coating layer, contact between the first wiring and the outside is prevented, and noise can be reduced. Furthermore, since the first insulating coating layer is expanded to a region where the first wiring and the third wiring are electrically connected by the conductive member, breakage or the like of the wiring is easily prevented.

Preferably, one embodiment of the stretchable device further includes: a second insulating coating layer coating the second wiring, and the second insulating coating layer overlaps the conductive member when viewed from a direction orthogonal to the fourth main surface.

According to the above embodiment, since the third wiring is covered with the second insulating coating layer, contact between the third wiring and the outside is prevented, and noise can be reduced. Furthermore, since the second insulating coating layer is expanded to a region where the first wiring and the third wiring are electrically connected by the conductive member, breakage or the like of the wiring is easily prevented.

Preferably, in one embodiment of the stretchable device, the first substrate is stretchable.

According to the above embodiment, since the first substrate is also stretchable, a stretching load applied to the second substrate can be reduced.

Preferably, in one embodiment of the stretchable device, the first wiring and the second wiring are stretchable.

According to the above embodiment, since the first wiring and the second wiring are also stretchable, a stretching load applied to the third wiring and the fourth wiring can be reduced.

Preferably, one embodiment of the stretchable device further includes: a third substrate having a fifth main surface and a sixth main surface facing each other; and a sixth wiring and a seventh wiring provided on the fifth main surface and extending along the fifth main surface, and the second substrate and the third substrate are connected, and a shortest distance between the sixth wiring and the seventh wiring is shorter than a shortest distance between the third wiring and the fourth wiring.

According to the above embodiment, it is possible to manufacture the stretchable device having a more complicated configuration.

According to the stretchable device according to an aspect of the present disclosure, the stretchable device has a low degree of manufacturing difficulty, and it is possible to manufacture the stretchable device with high yield.

### BRIEF EXPLANATION OF THE DRAWINGS

FIG. 1 is a plan view illustrating a first embodiment of a stretchable device.

FIG. 2 is a sectional view taken along I-I of FIG. 1.

FIG. 3 is a partial sectional view illustrating the first embodiment of the stretchable device and illustrating a first substrate side wiring and a second substrate side wiring.

FIG. 4A is a sectional view illustrating the first embodiment of the stretchable device.

FIG. 4B is a sectional view illustrating the first embodiment of the stretchable device.

FIG. 5 is a plan view illustrating a second embodiment of the stretchable device.

FIG. 6A is an enlarged plan view illustrating a third embodiment of the stretchable device and illustrating the first substrate side wiring and the second substrate side wiring.

FIG. 6B is an enlarged plan view illustrating the third embodiment of the stretchable device and illustrating the first substrate side wiring and the second substrate side wiring.

FIG. 7 is an enlarged plan view illustrating a fourth embodiment of the stretchable device and illustrating the first substrate side wiring and a fifth wiring.

FIG. 8 is a sectional view taken along II-II of FIG. 7.

FIG. 9 is a partial sectional view illustrating a fifth embodiment of the stretchable device and illustrating the first substrate side wiring and the second substrate side wiring.

FIG. 10 is a partial sectional view illustrating a sixth embodiment of the stretchable device and illustrating the first substrate side wiring and the second substrate side wiring.

FIG. 11 is a sectional view taken along III-III of FIG. 10.

FIG. 12 is a sectional view illustrating a seventh embodiment of the stretchable device.

FIG. 13 is a plan view illustrating an eighth embodiment of the stretchable device.

FIG. 14 is a plan view illustrating a ninth embodiment of the stretchable device.

FIG. 15A is an enlarged plan view illustrating the ninth embodiment of the stretchable device and illustrating the first substrate side wiring and the second substrate side wiring.

FIG. 15B is an enlarged plan view illustrating the ninth embodiment of the stretchable device and illustrating the first substrate side wiring and the second substrate side wiring.

### DESCRIPTION OF THE PREFERRED EMBODIMENTS

Hereinafter, a stretchable device according to an aspect of the present disclosure will be described in detail with reference to an illustrated embodiment. Note that the drawings include some schematic drawings and do not reflect actual dimensions or ratios in some cases.

### First Embodiment

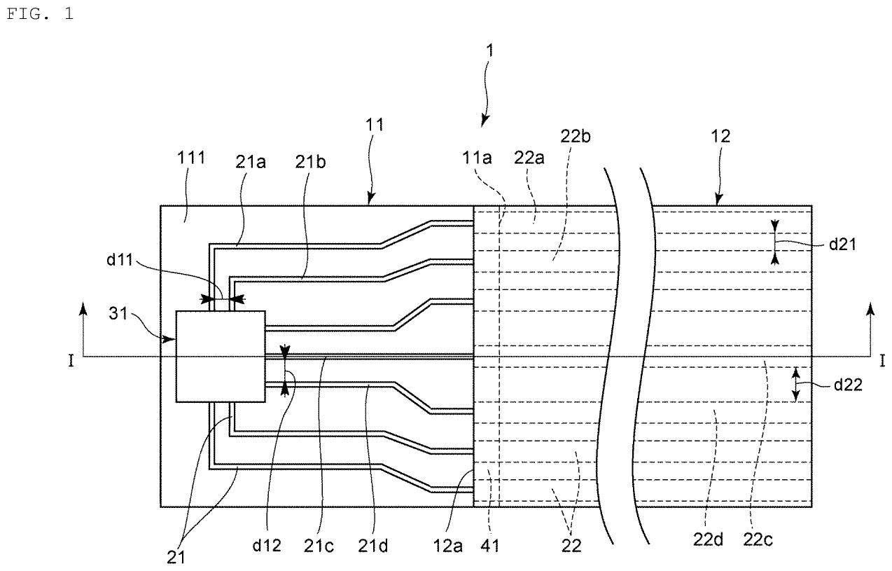

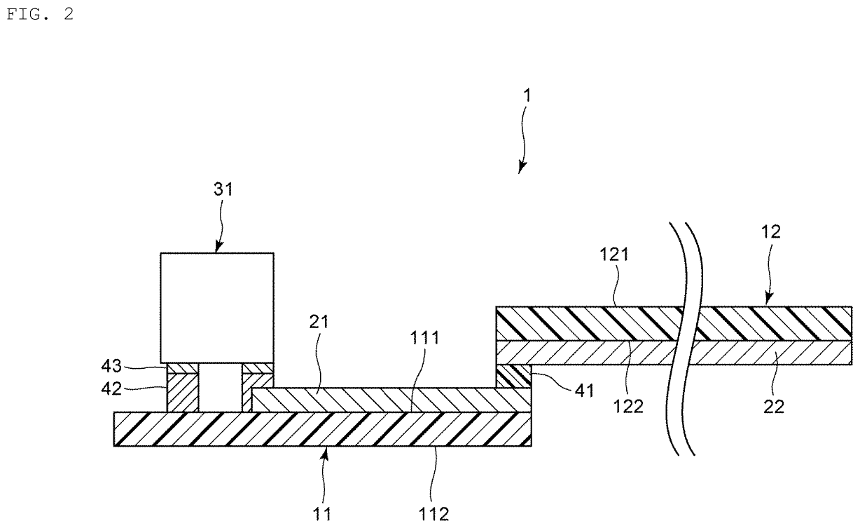

FIG. 1 is a plan view illustrating a first embodiment of the stretchable device. FIG. 2 is a sectional view taken along I-I of FIG. 1. The stretchable device is used, for example, to measure a biological signal by being brought into contact with a living body.

As illustrated in FIGS. 1 and 2, the stretchable device 1 includes a first substrate 11, a plurality of first substrate side wirings 21 provided on the first substrate 11, a first electronic component 31 provided on the first substrate 11, a stretchable second substrate 12, and a plurality of stretchable second substrate side wirings 22 provided on the second substrate 12. One of the first substrate side wirings 21 adjacent to each other corresponds to a first wiring described in the claims, and another one corresponds to a second wiring described in the claims. Further, one of the second substrate side wirings 22 adjacent to each other corresponds to a third wiring described in the claims, and another one corresponds to a fourth wiring described in the claims.

The first substrate 11 is formed of a resin material, for example, styrene resin, olefin resin, epoxy resin, urethane resin, polyimide resin, fluororesin, polyphenylene oxide resin, phenol resin, bismaleimide resin, acrylic resin, or silicone resin, and may include fibers such as a glass fiber and a paper fiber. The first substrate 11 may be stretchable. When the first substrate 11 is stretchable, a stretching load applied to the second substrate 12 can be reduced. Further, the first substrate 11 may be a non-stretchable substrate such as a printed circuit board (PCB).

A stretch ratio of the first substrate 11 is preferably 100% to 1000%. By setting the stretch ratio, it is easy to form a wiring having a complicated structure on the first substrate 11. Young's modulus of the first substrate 11 is preferably 0.1 to 50 MPa. By setting the above Young's modulus, it is easy to form a wiring having a complicated structure on the first substrate 11. Thickness of the first substrate 11 is, for example, 10 to 100 μm.

The first substrate 11 has a first main surface 111 and a second main surface 112 facing each other. The first substrate 11 is formed in a rectangular shape in plan view, and is arranged such that one end side 11a of the first substrate 11 faces the second substrate 12.

The first substrate side wiring 21 is formed of a conductive material. As the conductive material, for example, metal foil of silver, copper, nickel or the like may be used, or a mixture of metal powder of silver, copper, nickel or the like and elastomeric resin such as epoxy resin, urethane resin, acrylic resin, or silicone resin may be used. Thickness of the metal foil is preferably 0.01 μm to 10 μm, and an average particle D50 of the metal powder is preferably 0.01 μm to 10 μm. A shape of the metal powder may be a spherical shape, a flat shape, an irregular shape having a protrusion, or the like. The first substrate side wiring 21 may be stretchable. When the first substrate side wiring 21 is stretchable, a stretching load applied to the second substrate side wiring 22 can be reduced.

Thickness of the first substrate side wiring 21 is preferably 100 μm or less, more preferably 50 μm or less, and preferably 1 μm or more, more preferably 10 μm or more. The thinner the thickness of the first substrate side wiring 21, the smaller the unevenness and the easier the lamination and the like. Width of the first substrate side wiring 21 is preferably 100 μm to 10,000 μm, and more preferably 300 μm to 4,000 μm.

The first substrate side wiring 21 is arranged on the first main surface 111. That is, the first wiring and the second wiring described in the claims are both arranged on the first main surface 111 and exist on the same main surface. The first substrate side wiring 21 is formed by screen printing, inkjet printing, dispensing, or etching of metal foil so as to be in direct contact with the first main surface 111. Note that the first substrate side wiring 21 may be arranged on the first main surface 111 with another member such as an insulating member (not illustrated) interposed between them. Further, the first substrate side wiring 21 may be covered with an insulating coating layer (not illustrated).

Note that the number of the first substrate side wirings 21 only needs to be two or more. In a case where the number of the first substrate side wirings 21 is three or more, the first wiring and the second wiring described in the claims refer to optional two adjacent wirings among the first substrate side wirings 21. That is, the first substrate side wiring 21 may include a wiring other than the first wiring and the second wiring described in the claims.

Further, the first substrate side wiring 21 includes a first region overlapping the first electronic component 31 or a terminal of the first electronic component 31 when viewed from a direction perpendicular to the first substrate 11, and a second region not overlapping the first electronic component 31 or a terminal of the first electronic component 31. A shortest distance between the first wiring and the second wiring described in the claims refers to a shortest distance between the second regions of the wirings.

Each of a plurality of the first substrate side wirings 21 extends along the first main surface 111. A plurality of the first substrate side wirings 21 may be arranged separately without intersecting each other. In FIG. 1, the first substrate side wiring 21 is constituted by a straight portion and a corner portion, but is not limited to this, and may have a curved portion.

The second substrate 12 is formed of a stretchable resin material, for example, styrene resin, olefin resin, epoxy resin, urethane resin, acrylic resin, or silicone resin, and is preferably formed of urethane resin. Examples of the urethane resin include thermoplastic polyurethane (TPU). Examples of the styrene resin include styrene-butadiene-styrene copolymer resin (SBS).

A stretch ratio of the second substrate 12 is preferably 50% or more. By setting the above stretch ratio, followability of the stretchable device to a living body becomes excellent. Young's modulus of the second substrate 12 is preferably 100 MPa or less, and more preferably 30 MPa or less. By setting the above Young's modulus, discomfort of the user can be reduced. Thickness of the second substrate 12 is, for example, 0.1 to 100 μm.

The second substrate 12 includes a third main surface 121 and a fourth main surface 122 facing each other. The second substrate is formed in a rectangular shape, and is arranged such that one end side 12a of the second substrate 12 faces the one end side 11a of the first substrate 11.

The second substrate side wiring 22 is formed of a conductive material having stretchability. For the conductive material, for example, a mixture of metal powder of silver, copper, nickel or the like and elastomeric resin such as silicone is used.

The second substrate side wiring 22 is arranged on the fourth main surface 122. That is, the third wiring and the fourth wiring described in the claims are both arranged on the fourth main surface 122 and exist on the same main surface. Each of the second substrate side wirings 22 is formed by printing so as to be in direct contact with the fourth main surface 122. Note that the second substrate side wiring 22 may be arranged on the fourth main surface 122 with another member such as an insulating member (not illustrated) interposed between them. Further, the second substrate side wiring 22 may be covered with an insulating coating layer (not illustrated).

Note that the number of the second substrate side wirings 22 only needs to be two or more. In a case where the number of the second substrate side wirings 22 is three or more, the third wiring and the fourth wiring described in the claims refer to optional two adjacent wirings among the second substrate side wirings 22. That is, the second substrate side wiring 22 may include a wiring other than the third wiring and the fourth wiring described in the claims.

Each of a plurality of the second substrate side wirings 22 extends along the fourth main surface 122. A plurality of the second substrate side wirings 22 may be arranged separately without intersecting each other. Each of the second substrate side wirings 22 is electrically connected to the first substrate side wiring 21. The second substrate side wiring 22 corresponding to the third wiring may be electrically connected to the first substrate side wiring 21 corresponding to the first wiring, and the second substrate side wiring 22 corresponding to the fourth wiring may be electrically connected to the first substrate side wiring 21 corresponding to the second wiring. In FIG. 1, the second substrate side wiring 22 is constituted by a straight portion, but is not limited to this, and may have a curved portion.

A shortest distance d1 between adjacent ones of the first substrate side wirings 21 is shorter than a shortest distance d2 between adjacent ones of the second substrate side wirings 22. That is, a wiring pattern arranged on the first main surface 111 is finer than a wiring pattern arranged on the fourth main surface 122. For this reason, while a fine wiring pattern is formed on the first substrate 11, wirings are arranged on the stretchable second substrate 12 in a relatively sparsely dispersed manner. Therefore, degree of manufacturing difficulty is not high, and the manufacturing can be performed with high yield. Furthermore, since wirings are arranged on the second substrate 12 in a relatively sparsely dispersed manner, a stretching load can be relatively uniformly absorbed by the entire second substrate 12.

Regarding a case where the number of the first substrate side wirings 21 is n and n is two, a shortest distance between the wirings will be described. Hereinafter, predetermined ones of the first substrate side wirings will be referred to as 21a, 21b, 21c, and 21d, and predetermined ones of the second substrate side wirings will be referred to as 22a, 22b, 22c, and 22d.

The shortest distance d1 between adjacent ones of the first substrate side wirings 21a and 21b refers to a shortest value among measurement values obtained by sequentially measuring distances from the first substrate side wiring 21a on the one hand to the first substrate side wiring 21b on the other along the first substrate side wiring 21a on the one hand.

Further, the shortest distance d2 between adjacent ones of the second substrate side wirings 22a and 22b refers to a shortest value among measurement values obtained by sequentially measuring distances from the second substrate side wiring 22a on one hand to the second substrate side wiring 22b on the other hand along the second substrate side wiring 22a on the one hand.

That the shortest distance d1 between adjacent ones of the first substrate side wirings 21a and 21b is shorter than the shortest distance d2 between adjacent ones of the second substrate side wirings 22a and 22b means that d1 and d2 are compared and d1 has a smaller value.

Regarding a case where the number n of the first substrate side wirings 21 is three or more, a shortest distance between the wirings will be described.

A shortest distance between adjacent ones of the first substrate side wirings 21 refers to a smallest value among shortest distances between n-1 sets of adjacent ones of the first substrate side wirings 21.

In FIG. 1, a shortest distance between a first set of adjacent ones of the first substrate side wirings 21a and 21b is d11, and a shortest distance between a second set of adjacent ones of the first substrate side wirings 21c and 21d is d12. When the shortest distance d11 and the shortest distance d12 are compared, the shortest distance d11 is smaller. As described above, by comparing n−1 values, the shortest distance d1 that is a minimum value of the values can be obtained.

The shortest distance d2 between adjacent ones of the second substrate side wirings 22 refers to a smallest value among shortest distances between n−1 sets of adjacent ones of the second substrate side wirings 22.

In FIG. 1, a shortest distance between a first set of adjacent ones of the second substrate side wirings 22a and 21b is d21, and a shortest distance between a second set of adjacent ones of the second substrate side wirings 22c and 22d is d22. When the shortest distance d21 and the shortest distance d22 are compared, the shortest distance d21 is smaller. As described above, by comparing n−1 values, the shortest distance d2 that is a minimum value of the values can be obtained.

That a shortest distance between adjacent ones of the first substrate side wirings 21 is shorter than a shortest distance between adjacent ones of the second substrate side wirings 22 means that d1 and d2 are compared and d1 has a smaller value.

In FIG. 1, width of the first substrate side wiring 21 is narrower than width of the second substrate side wiring 22. Since width of the first substrate side wiring is narrower than width of the second substrate side wiring, it is easy to form a finer wiring pattern on the first substrate.

In FIGS. 1 and 2, the stretchable device 1 further includes a conductive member 41 that electrically connects the first substrate side wiring 21 and the second substrate side wiring 22. As a result, since the first wiring and the third wiring are electrically connected via the conductive member, connection reliability can be enhanced. Further, since it is not necessary to directly join the first wiring and the third wiring, alignment is facilitated, and degree of manufacturing difficulty can be lowered.

The first substrate 11 and the second substrate 12 are arranged such that the first main surface 111 and the fourth main surface 122 face each other. Further, the first substrate side wiring 21 and the second substrate side wiring 22 are arranged so as to face each other, and the conductive member 41 is arranged between the first substrate side wiring 21 and the second substrate side wiring 22. By the above, a portion where the first substrate side wiring 21 and the second substrate side wiring 22 overlap each other is generated, the conductive member 41 exists in this portion, and the first substrate side wiring 21 and the second substrate side wiring 22 are electrically connected via the conductive member 41, so that connection reliability can be further enhanced. Furthermore, since the first substrate 11 and the second substrate 12 may be connected by the conductive member 41, mechanical strength of a joint portion between the first substrate 11 and the second substrate 12 can be increased.

The conductive member 41 is, for example, an anisotropic conductive film (ACF), has conductivity in a direction orthogonal to the first main surface 111, and has insulating property in a planar direction. The conductive member 41 includes thermosetting epoxy resin and conductive particles arranged in a manner dispersed in the epoxy resin. Therefore, the first substrate side wiring 21 is conductive only to the second substrate side wiring 22 immediately above, and is not conductive to the first substrate side wiring 21 adjacent in a direction of the first main surface 111 or the second substrate side wiring 22 not immediately above.

Particle size of the conductive particles is, for example, 10 to 30 μm. As illustrated in FIG. 3, the particle size is preferably larger than a distance in a direction orthogonal to the first main surface 111 between the first substrate side wiring 21 and the second substrate side wiring 22. A surface of the conductive particles has conductivity, and when particle size of the conductive particles is larger than a distance between the first substrate side wiring 21 and the second substrate side wiring 22 electrically connected to each other, the surface of the conductive particles and the wiring are more reliably in contact with each other, so that the first substrate side wiring 21 and the second substrate side wiring 22 are more reliably electrically connected.

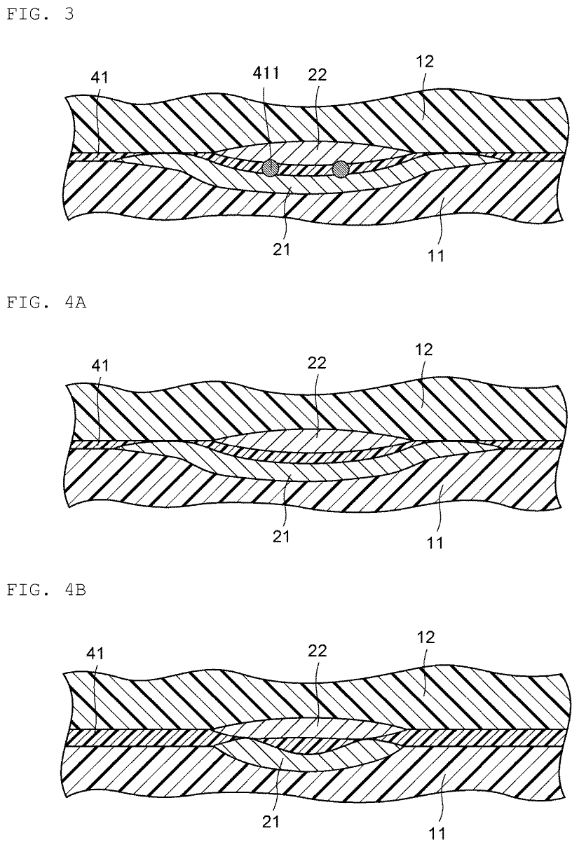

FIGS. 4A and 4B are partial sectional views illustrating the first substrate side wiring 21, the second substrate side wiring 22, and the conductive member 41. As illustrated in FIG. 4A, in a section orthogonal to a direction in which the first substrate side wiring 21 extends in a portion where the first substrate side wiring 21 and the second substrate side wiring 22 overlap, width of the first substrate side wiring 21 and width of the second substrate side wiring 22 are different, and the width of the second substrate side wiring 22 is narrower than the width of the first substrate side wiring 21. For this reason, in a case where the first substrate side wiring 21 and the second substrate side wiring 22 are connected with the conductive member 41 interposed between them, the conductive member 41 exists with unique thickness between the first substrate side wiring 21 and the second substrate side wiring 22, and the first substrate side wiring 21 and the second substrate side wiring 22 can be more reliably electrically connected.

When the first substrate side wiring 21 and the second substrate side wiring 22 are electrically connected via the conductive member 41, the conductive member 41 is arranged between the first substrate side wiring 21 and the second substrate side wiring 22, and thermocompression bonding is performed while applying pressure in a direction orthogonal to the first main surface. At this time, as illustrated in FIG. 4B, when width of the first substrate side wiring 21 and width of the second substrate side wiring 22 match, the first substrate side wiring 21 and the second substrate side wiring 22 are in contact with each other only at an end edge, and doming in which the conductive member 41 is confined at a central portion in a width direction is likely to occur. When the doming occurs, thickness in a direction orthogonal to the first main surface 111 at a central portion in the width direction increases at a connection portion between the first substrate side wiring 21 and the second substrate side wiring. For this reason, electrical connection via the conductive member 41 cannot be sufficiently achieved.

However, according to the above embodiment, since width of the first substrate side wiring 21 is different from width of the second substrate side wiring 22, the conductive member 41 is not confined and uniformly spreads during thermocompression bonding. As a result, the first substrate side wiring 21 and the second substrate side wiring 22 are more reliably electrically connected. Further, width of the first substrate side wiring 21 is different from width of the second substrate side wiring 22, and one of the wirings has a wider width than another one of the wirings. As a result, alignment is facilitated, and degree of manufacturing difficulty can be further lowered. Further, positional deviation can be reduced, and yield can be further improved.

Here, the width direction refers to a direction orthogonal to a direction in which the first substrate side wiring 21 extends along the first main surface 111. Further, a side edge of a wiring refers to an edge along an extending direction of the wiring. Further, a section orthogonal to a direction in which the first substrate side wiring 21 extends in a portion where the first substrate side wiring 21 and the second substrate side wiring 22 overlap is a sectional view in a central portion in the direction in which the first substrate side wiring 21 extends in the portion where the first substrate side wiring 21 and the second substrate side wiring 22 overlap.

The shortest distance d1 between adjacent ones of the first substrate side wirings 21 is less than 250 μm, and the shortest distance d2 between adjacent ones of the second substrate side wirings 22 is 250 μm or more. By the above, it becomes easier to adjust a difference in degree of manufacturing difficulty according to a type of substrate, and as a result, degree of manufacturing difficulty of the stretchable device can be further lowered and the stretchable device can be manufactured with higher yield. Further, in a section orthogonal to a direction in which the first substrate side wiring 21 extends in a portion where the first substrate side wiring 21 and the second substrate side wiring 22 overlap, width of one having a narrower width between the first substrate side wiring 21 and the second substrate side wiring 22 is preferably 500 μm or less, and may be 300 μm or less.

In FIG. 4, width of the second substrate side wiring 22 is narrower than width of the first substrate side wiring 21, but the present disclosure is not limited to this, and width of the first substrate side wiring 21 may be narrower than width of the second substrate side wiring 22.

The first electronic component 31 includes, for example, a connector, an element, and a control circuit.

The first electronic component 31 is arranged only on the first main surface 111 and is electrically connected to a plurality of the first substrate side wirings 21. By the above, since an electronic component is provided only on the first substrate, it is easy to further lower degree of manufacturing difficulty of the second substrate.

In FIGS. 1 and 2, the first substrate side wiring 21 and the electronic component 31 are electrically connected via a mounting electrode 42 and solder 43. The electronic component 31 has a terminal (not illustrated). Specifically, an end portion of the first substrate side wiring 21 is covered with the mounting electrode 42, and the electronic component 31 is electrically connected to the mounting electrode 42 via the solder 43. For the mounting electrode 42, a mixture of metal powder of silver, copper, or the like and thermosetting resin such as epoxy resin is used. By interposing the mounting electrode between the first wiring and the solder, it is possible to more reliably electrically connect the first substrate side wiring and the electronic component 31 without deformation of the first substrate side wiring 21 at the time of solder bonding.

In the above embodiment, in a section orthogonal to a direction in which the first substrate side wiring 21 extends in a portion where the first substrate side wiring 21 and the second substrate side wiring 22 overlap, width of the second substrate side wiring 22 is narrower than width of the first substrate side wiring 21, but the present disclosure is not limited to this. Width of the first substrate side wiring 21 may be narrower than width of the second substrate side wiring 22.

In the above embodiment, the first substrate side wiring 21 and the second substrate side wiring 22 are electrically connected via the conductive member 41, but the present disclosure is not limited to this, and the first substrate side wiring and the second substrate side wiring may be electrically connected by direct contact between the first substrate side wiring and the third substrate side wiring.

### Second Embodiment

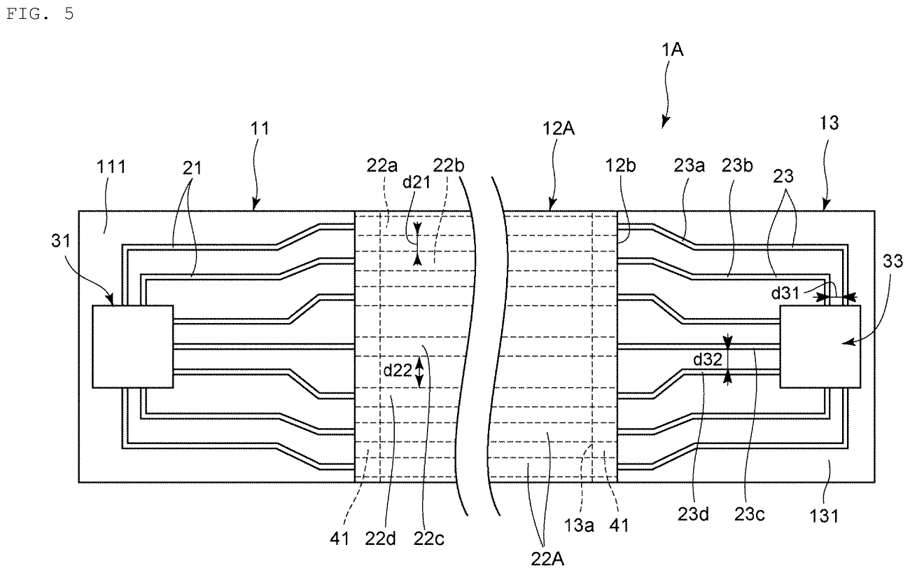

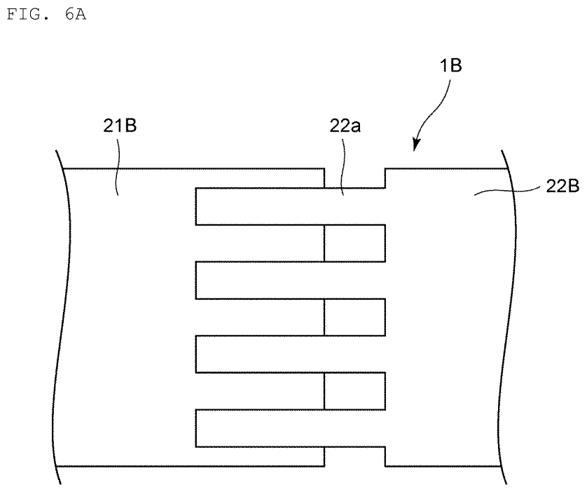

FIG. 5 is a plan view illustrating a second embodiment of the stretchable device. The second embodiment is different from the first embodiment in further including a third substrate and a third substrate side wiring arranged on the third substrate. This different configuration will be described below. The other configurations are the same as those of the first embodiment, are denoted by the same reference symbols as those of the first embodiment, and will be omitted from description.

As illustrated in FIG. 5, in a stretchable device 1A of the second embodiment, a second substrate 12A further includes an end side 12b, and further includes a third substrate 13, and a plurality of third substrate side wirings 23 and a third electronic component 33 provided on the third substrate 13. One of the third substrate side wirings adjacent to each other corresponds to a sixth wiring described in the claims, and another one corresponds to a seventh wiring described in the claims. This makes it possible to manufacture a stretchable device having a more complicated configuration.

The third substrate 13 is formed of a resin material, for example, epoxy resin, urethane resin, acrylic resin, silicone resin, phenol resin, or polyimide resin, and may contain a glass fiber and a paper fiber.

A stretch ratio of the third substrate 13 is preferably 100% to 1000%. By setting the stretch ratio, it is easy to form a complicated wiring on the third substrate 13. Young's modulus of the third substrate 13 is preferably 0.1 to 50 MPa. By setting the above Young's modulus, it is easy to form a complicated wiring on the third substrate 13. Thickness of the third substrate 13 is, for example, 10 to 100 μm.

The third substrate 13 has a fifth main surface 131 and a sixth main surface 132 facing each other. The third substrate 13 is formed in a rectangular shape in plan view, and is arranged such that one end side 13a of the third substrate 13 faces the end side 12b of the second substrate 12.

The third substrate side wiring 23 is formed of a conductive material. As the conductive material, for example, metal foil of silver, copper, or the like may be used, or a mixture of metal powder of silver, copper, or the like and elastomeric resin of silicone or the like may be used. A mixture of elastomer resin such as epoxy resin, urethane resin, acrylic resin, or silicone resin may be used. Thickness of the metal foil is preferably 0.01 μm to 10 μm, and an average particle D50 of the metal powder is preferably 0.01 μm to 10 μm. A shape of the metal powder may be a spherical shape, a flat shape, an irregular shape having a protrusion, or the like. The third substrate side wiring 23 may be stretchable.

Thickness of the third substrate side wiring 23 is preferably 100 μm or less, more preferably 50 μm or less, and preferably 1 μm or more, more preferably 10 μm or more. The thinner the thickness of the third substrate side wiring 23, the smaller the unevenness and the easier the lamination and the like. Width of the third substrate side wiring 23 is preferably 100 μm to 10,000 μm, and more preferably 300 μm to 4,000 μm.

The third substrate side wiring 23 is arranged on the fifth main surface 131. That is, the sixth wiring and the seventh wiring described in the claims are both arranged on the fifth main surface 131 and exist on the same main surface. The third substrate side wiring 23 is formed by screen printing, inkjet printing, dispensing, or etching of metal foil so as to be in direct contact with the fifth main surface 131. Note that the third substrate side wiring 23 may be arranged on the fifth main surface 131 with another member such as an insulating member (not illustrated) interposed between them. Further, the third substrate side wiring 23 may be covered with an insulating coating layer (not illustrated).

Further, the third substrate side wiring 23 includes a third region overlapping the third electronic component 33 or a terminal of the third electronic component 33 when viewed from a direction perpendicular to the fifth substrate 131, and a fourth region not overlapping the third electronic component 33 or a terminal of the third electronic component 33. A shortest distance between the sixth wiring and the seventh wiring described in the claims refers to a shortest distance between the fourth regions of the wirings.

A plurality of the third substrate side wirings 23 extend along the fifth main surface 131. A plurality of the third substrate side wiring may be arranged separately without intersecting each other. A plurality of the third substrate side wirings 23 extend along the fifth main surface 131. Each of the third substrate side wiring 23 is electrically connected to the second substrate side wiring 22. The third substrate side wiring 23 corresponding to the sixth wiring may be electrically connected to the second substrate side wiring corresponding to the third wiring, and the third substrate side wiring 23 corresponding to the seventh wiring may be electrically connected to the second substrate side wiring 22 corresponding to the fourth wiring. In FIG. 5, the third substrate side wiring 23 is constituted by a straight portion and a corner portion, but is not limited to this, and may have a curved portion.

A shortest distance d3 between adjacent ones of the third substrate side wiring 23 is shorter than the shortest distance d2 between adjacent ones of the second substrate side wirings 22. That is, a wiring pattern arranged on the fifth main surface 131 is finer than a wiring pattern arranged on the fourth main surface 122. For this reason, while a fine wiring pattern is formed on the third substrate 13, wirings are arranged on the stretchable second substrate 12 in a relatively sparsely dispersed manner. Therefore, degree of manufacturing difficulty is not high, and the manufacturing can be performed with high yield. Furthermore, since wirings are arranged on the second substrate 12 in a relatively sparsely dispersed manner, a stretching load can be relatively uniformly absorbed by the entire second substrate 12.

Regarding a case where the number n of the third substrate side wiring 23 is two, a shortest distance between the wirings will be described.

The shortest distance d3 between the third substrate side wirings 23 refers to a shortest value among measurement values obtained by sequentially measuring distances from one third substrate side wiring 23a to another third substrate side wiring 23b along the one third substrate side wiring 23a.

That the shortest distance d3 between adjacent ones of the third substrate side wirings 23 is shorter than the shortest distance d2 between adjacent ones of the second substrate side wirings 22 means that d3 and d2 are compared and d3 has a smaller value.

Regarding a case where the number n of the third substrate side wirings 23 is three or more, a shortest distance between the wirings will be described. Hereinafter, predetermined ones of the second substrate side wirings will be referred to as 22a, 22b, 22c, and 22d, and predetermined ones of the third substrate side wirings will be referred to as 23a, 23b, 23c, and 23d.

A shortest distance between adjacent ones of the third substrate side wirings 23 refers to a smallest value among shortest distances between n-1 sets of adjacent ones of the third substrate side wirings 23.

In FIG. 5, a shortest distance between a first set of adjacent ones of the third substrate side wirings 23a and 23b is d31, and a shortest distance between a second set of adjacent ones of the third substrate side wirings 23c and 23d is d32. When the shortest distance d31 and the shortest distance d32 are compared, the shortest distance d31 is smaller. As described above, by obtaining n-1 shortest distances and comparing these values, the shortest distance d3 that is a minimum value of the shortest distances can be obtained.

That a shortest distance between adjacent ones of the third substrate side wirings 23 is shorter than a shortest distance between adjacent ones of the second substrate side wirings 22 means that d3 and d2 are compared and d3 has a smaller value.

The third electronic component 33 includes, for example, a connector, an element, and a control circuit.

The third electronic component 33 is arranged on the fifth main surface 131 and is electrically connected to a plurality of the third substrate side wirings 23. Since an effect of the other configurations are the same as that of the first embodiment, description of the effect will be omitted.

### Third Embodiment

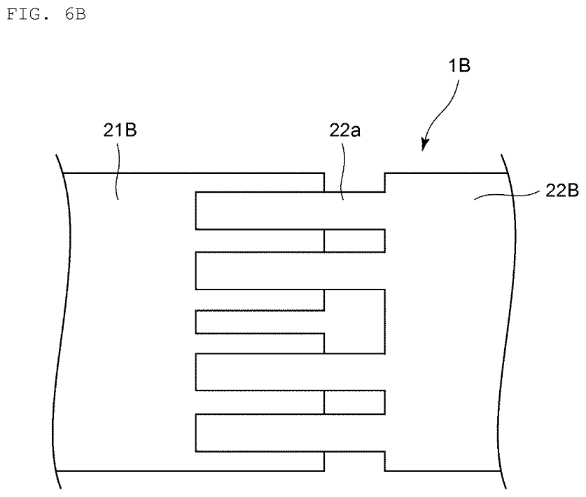

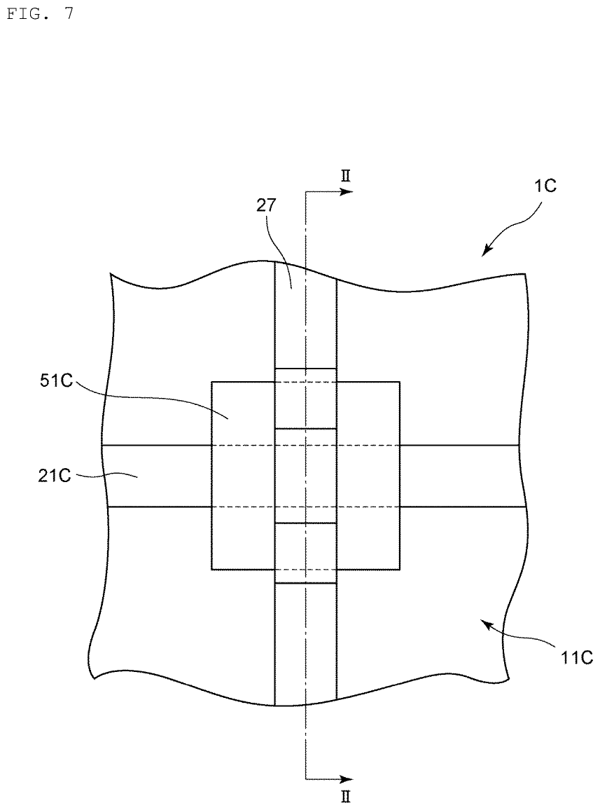

FIGS. 6A and 6B are enlarged plan views illustrating a third embodiment of the stretchable device and illustrating the first substrate side wiring and the second substrate side wiring. The third embodiment is different from the first embodiment in configurations of the first substrate side wiring and the second substrate side wiring. This different configuration will be described below. The other configurations are the same as those of the first embodiment, are denoted by the same reference symbols as those of the first embodiment, and will be omitted from description.

In a stretchable device 1B of the third embodiment, at least one of a first substrate side wiring 21B and a second substrate side wiring 22B has a comb-tooth-shaped end portion, and preferably, the second substrate side wiring 22B has a comb-tooth-shaped end portion. By the above, when the first substrate side wiring 21B and the second substrate side wiring 22B are electrically connected via a conductive member (not illustrated), the conductive member can flow out between comb teeth and is not confined between the first substrate side wiring 21B and the second substrate side wiring 22B, so that doming is prevented and electrical connection between the first substrate side wiring 21B and the second substrate side wiring 22B becomes excellent.

A comb-tooth-shaped end portion has a plurality of tooth portions 22a provided in parallel and separately in the width direction, and an interval between two adjacent ones of the tooth portions 22a is preferably 700 μm or less for all the tooth portions 22a. By the above, an area of a portion where the first substrate side wiring 21B and the second substrate side wiring 22B overlap is increased, so that the first substrate side wiring 21B and the second substrate side wiring 22B are more reliably electrically connected. Further, an interval between two adjacent ones of the tooth portions 22a is preferably 200 μm or more for all the tooth portions 22a. By the above, a doming prevention effect is more reliably exhibited, and electrical connection between the first substrate side wiring 21B and the second substrate side wiring 22B is further improved. Further, an interval between two adjacent ones of the tooth portions 22a is the same for all the tooth portions. By the above, since a plurality of tooth portions are arranged at equal intervals in the width direction, the first wiring and the third wiring are more reliably electrically connected.

Further, an interval between two adjacent ones of the tooth portions 22a may be 0.5 to 2 times or 0.8 to 1.2 times the width of the tooth portion.

Only at least a part of the tooth portion 22a needs to overlap the first substrate side wiring 21B, and all the tooth portions 22a may overlap the first substrate side wiring 21B.

In FIG. 6A, the second substrate side wiring 22B has a comb-tooth-shaped end portion, but the present disclosure is not limited to this, and the first substrate side wiring 21B may have a comb-tooth-shaped end portion on the side connected to the second substrate side wiring 22B. In this case, the number of tooth portions provided at an end portion of the second substrate side wiring 22B and the number of tooth portions provided at an end portion connected to the second substrate side wiring 22B of the first substrate side wiring 21B may be the same or different. The number of tooth portions provided at an end portion of the second substrate side wiring 22B may be twice the number of tooth portions provided at an end portion connected to the second substrate side wiring 22B of the first substrate side wiring 21B. For example, as illustrated in FIG. 6B, the number of tooth portions provided at an end portion of the second substrate side wiring 22B may be four, and the number of tooth portions provided at an end portion connected to the second substrate side wiring 22B of the first substrate side wiring 21B may be two. The number of tooth portions provided at an end portion of the second substrate side wiring 22B may be ½ times the number of tooth portions provided at an end portion connected to the second substrate side wiring 22B of the first substrate side wiring 21B. Furthermore, the number of tooth portions provided at an end portion of the second substrate side wiring 22B may be two, and the number of tooth portions provided at an end portion connected to the second substrate side wiring 22B of the first substrate side wiring 21B may be four. Further, in FIG. 6B, the number of tooth portions provided at a comb-tooth-shaped end portion is two or four, but the present disclosure is not limited to this, and the number can be freely increased or decreased. Since an effect of the other configurations are the same as that of the first embodiment, description of the effect will be omitted.

### Fourth Embodiment

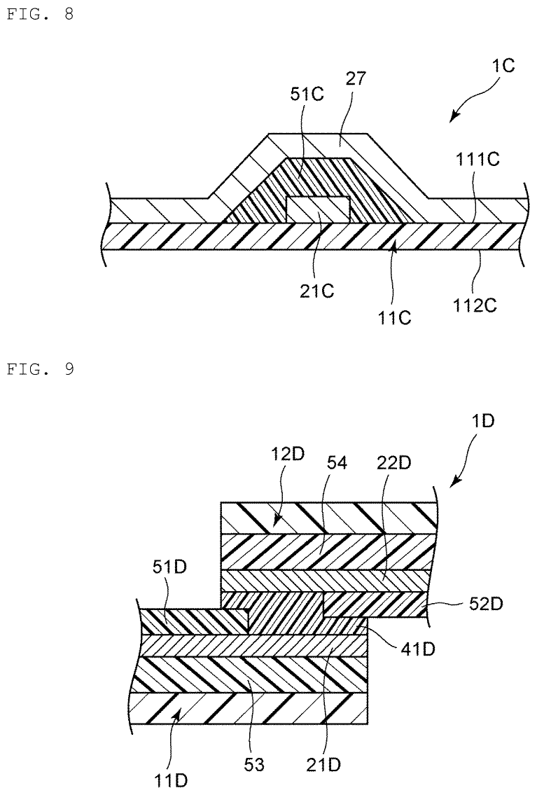

FIG. 7 is an enlarged plan view illustrating a fourth embodiment of the stretchable device and illustrating the first substrate side wiring and a fifth wiring. FIG. 8 is a sectional view taken along II-II of FIG. 7. The fourth embodiment is different from the first embodiment in a configuration including the fifth wiring. This different configuration will be described below. The other configurations are the same as those of the first embodiment, are denoted by the same reference symbols as those of the first embodiment, and will be omitted from description.

As illustrated in FIGS. 7 and 8, the stretchable device 1C of the fourth embodiment further includes a fifth wiring 27 provided on a first main surface 111C, and the fifth wiring 27 has a region overlapping a first substrate side wiring 21C when viewed from a direction orthogonal to the first main surface 111C. That is, overlapping in a direction orthogonal to the first main surface 111C of a wiring arranged on a first substrate 11C is lower than overlapping in a direction orthogonal to the fourth main surface 122 of a wiring arranged on the second substrate 12C. By the above, a more complicated wiring pattern is arranged on the first substrate 11, a wiring pattern on the second substrate 12 can be simplified, and degree of manufacturing difficulty of the second substrate can be further lowered.

The fifth wiring 27 is formed of a conductive material. As the conductive material, for example, metal foil of silver, copper, nickel or the like may be used, or a mixture of metal powder of silver, copper, nickel or the like and elastomeric resin such as epoxy resin, urethane resin, acrylic resin, or silicone resin may be used. Thickness of the metal foil is preferably 0.01 μm to 10 μm, and an average particle D50 of the metal powder is preferably 0.01 μm to 10 μm. A shape of the metal powder may be a spherical shape, a flat shape, an irregular shape having a protrusion, or the like. The fifth wiring 27 may be stretchable. When the fifth wiring 27 is stretchable, in a case where the fifth wiring is formed on the first substrate side wiring, it is easy to prevent disconnection and the like.

Thickness of the fifth wiring 27 is preferably 100 μm or less, more preferably 50 μm or less, and preferably 1 μm or more, more preferably 10 μm or more. The thinner the thickness of the fifth wiring 27, the less the unevenness and the easier the lamination and the like. Width of the fifth wiring 27 is preferably 100 μm to 10,000 μm, and more preferably 300 μm to 4,000 μm.

The fifth wiring 27 is arranged on the first main surface 111C. The fifth wiring 27 is formed on the first main surface 111C by screen printing, inkjet printing, dispensing, or etching of metal foil. The fifth wiring 27 and the first substrate side wiring 21C are electrically insulated by an insulating member 51C. Further, the fifth wiring 27 may be covered with an insulating coating layer (not illustrated).

The fifth wiring 27 intersects the first substrate side wiring 21C when viewed from a direction orthogonal to the first main surface 111C. In FIG. 7, the fifth wiring 27 and the first substrate side wiring 21C are orthogonal to each other, but the present disclosure is not limited to this, and an intersection angle can be freely increased or decreased. Further, in FIG. 7, a seventh substrate side wiring is constituted by a straight portion, but is not limited to this, and may have a corner portion and a curved portion.

Furthermore, in FIG. 7, only the fifth wiring 27 and the first substrate side wiring 21C are illustrated, but the present disclosure is not limited to this. In the stretchable device 1C, for example, eighth wirings electrically connected to the fifth wiring 27, arranged separately without intersecting each other, and extending along the fourth main surface may be further arranged on the fourth main surface. A configuration of the eighth wiring is the same as a configuration of the second substrate side wiring. Further, in the stretchable device 1C, for example, a fourth electronic component electrically connected to the fifth wiring 27 may be arranged on the first main surface 111C. A configuration of the fourth electronic component is the same as a configuration of the first electronic component. Since an effect of the other configurations are the same as that of the first embodiment, description of the effect will be omitted.

### Fifth Embodiment

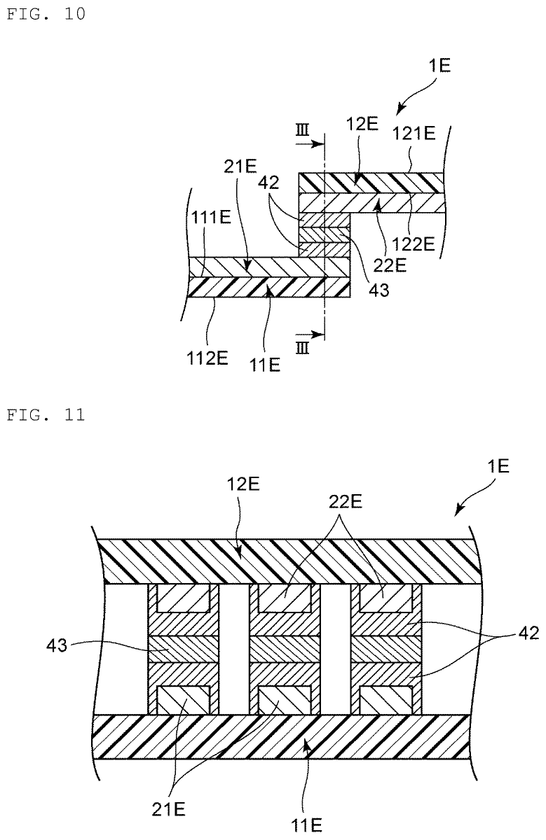

FIG. 9 is a partial sectional view illustrating a fifth embodiment of the stretchable device and illustrating the first substrate side wiring and the second substrate side wiring. The fifth embodiment is different from the first embodiment in a configuration including an insulating coating layer. This different configuration will be described below. The other configurations are the same as those of the first embodiment, are denoted by the same reference symbols as those of the first embodiment, and will be omitted from description.

As illustrated in FIG. 9, in a stretchable device 1D of the fifth embodiment, a first substrate side wiring 21D is formed on a first main surface 111D with a first insulating member 53 interposed between them, and the first substrate side wiring 21D is covered with a first insulating coating layer 51. Further, a second substrate side wiring 22D is formed on a fourth main surface 122D with a second insulating member 54 interposed between them, and the second substrate side wiring 22D is covered with a second insulating coating layer 52. Further, the first substrate side wiring 21D and the second substrate side wiring 22D, and a conductive member 41D are arranged so as to overlap each other in a direction orthogonal to the first main surface 111, and the first insulating coating layer 51 overlaps the conductive member 41D when viewed from a direction orthogonal to the first main surface 111D. Further, the second insulating coating layer overlaps the conductive member 41D when viewed from a direction orthogonal to the fourth main surface 122D.

In the present embodiment, since the first substrate side wiring 21D is covered with the first insulating coating layer 51, contact between the first substrate side wiring 21D and the outside is prevented, and noise can be reduced. Furthermore, the first insulating coating layer 51 has a region arranged between the second substrate side wiring 22D and the conductive member 41D in a direction orthogonal to the first main surface 111D. For this reason, breakage of the first substrate side wiring 21D can be easily prevented. Further, since the second substrate side wiring 22D is covered with the second insulating coating layer 52, contact between the second substrate side wiring 22D and the outside is prevented, and noise can be reduced. Furthermore, the second insulating coating layer 52 has a region arranged between the first substrate side wiring 21D and the conductive member 41D in a direction orthogonal to the first main surface 111D. Therefore, breakage of the second substrate side wiring 22D is easily prevented.

In FIG. 9, the first substrate side wiring 21D is formed on the first main surface 111D with the first insulating member 53 interposed between them, but the present disclosure is not limited to this, and the first substrate side wiring 21D may be formed without the first insulating member 53 interposed between them. Further, the second substrate side wiring 22D is formed on the fourth main surface 122D with the second insulating member 54 interposed between them, but the present disclosure is not limited to this, and the second substrate side wiring 22D may be formed without the second insulating member 54 interposed between them. Since an effect of the other configurations are the same as that of the first embodiment, description of the effect will be omitted.

### Sixth Embodiment

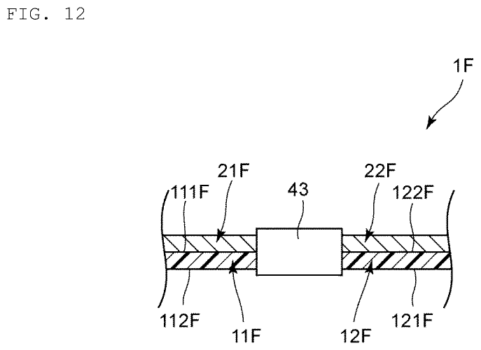

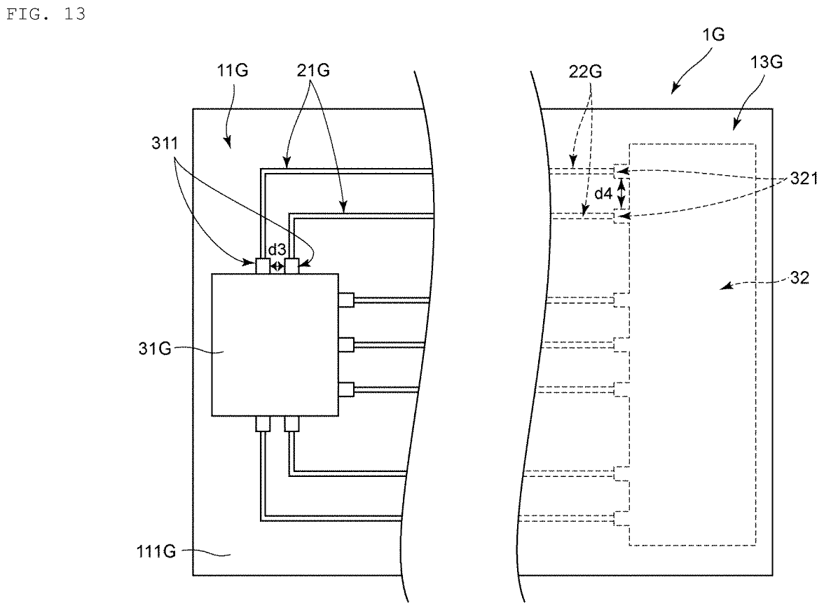

FIG. 10 is a sectional view illustrating a sixth embodiment of the stretchable device and illustrating the first substrate side wiring and the second substrate side wiring. FIG. 11 is a sectional view taken along III-III of FIG. 10. The sixth embodiment is different from the first embodiment in a configuration in which the first substrate side wiring and the second substrate side wiring are electrically connected via solder and a mounting electrode. This different configuration will be described below. The other configurations are the same as those of the first embodiment, are denoted by the same reference symbols as those of the first embodiment, and will be omitted from description.

As illustrated in FIGS. 10 and 11, in a stretchable device 1E of the sixth embodiment, a first substrate side wiring 21E and a second substrate side wiring 22E are electrically connected via the mounting electrode 42 and the solder 43. Specifically, each of end portions of the first substrate side wiring 21E and the second substrate side wiring 22E is covered with the mounting electrode 42, and each of the mounting electrodes 42 is electrically connected via the solder 43. By the above, electrical connection between the first substrate side wiring 21E and the second substrate side wiring 22E is ensured, and it is possible to cope with various manufacturing modes of the stretchable device. Further, by interposing the mounting electrode 42 between the first substrate side wiring 21E and the second substrate side wiring 22E, and the solder 43, the first substrate side wiring 21E and the second substrate side wiring 22E are less likely to be deformed at the time of solder bonding, so that the first substrate side wiring 21E and the second substrate side wiring 22E can be more reliably electrically connected.

For the mounting electrode, a mixture of metal powder of silver, copper, or the like and thermosetting resin such as epoxy resin is used. Since an effect of the other configurations are the same as that of the first embodiment, description of the effect will be omitted.

In the present embodiment, the first substrate side wiring and the second substrate side wiring are electrically connected via the mounting electrode and the solder, but the present disclosure is not limited to this, and the first substrate side wiring and the second substrate side wiring may be electrically connected via the mounting electrode and a conductive adhesive.

### Seventh Embodiment

FIG. 12 is a sectional view illustrating a seventh embodiment of the stretchable device. The seventh embodiment is different from the second embodiment in a configuration of the second substrate and a configuration using a connector instead of a conductive member for electrical connection between the first substrate side wiring and the second substrate side wiring. This different configuration will be described below. The other configurations are the same as those of the first embodiment, are denoted by the same reference symbols as those of the first embodiment, and will be omitted from description.

As illustrated in FIG. 12, in a stretchable device 1F of the seventh embodiment, a second substrate 12F is arranged such that a fourth main surface 122F faces the same direction as a first main surface 111F, and a first substrate side wiring 21F and a second substrate side wiring 22F are electrically connected via a connector 44. At the same time, a first substrate 11F and the second substrate 12F are connected via the connector 44. Since the first substrate side wiring 21 and the second substrate side wiring 22F are electrically connected to each other via the connector 44, mechanical strength at a connection portion is increased.

In FIG. 12, the first substrate side wiring 21F and the second substrate side wiring 22F are electrically connected via the connector 44, but similarly, the second substrate side wiring 22F and the third substrate side wiring may be electrically connected via the connector. Since an effect of the other configurations are the same as that of the first embodiment, description of the effect will be omitted.

### Eighth Embodiment

FIG. 13 is a plan view illustrating an eighth embodiment of the stretchable device. The eighth embodiment is different from the first embodiment in a configuration including a second electronic component on the second substrate. This different configuration will be described below. The other configurations are the same as those of the first embodiment, are denoted by the same reference symbols as those of the first embodiment, and will be omitted from description.

As illustrated in FIG. 13, in a stretchable device 1G of the eighth embodiment, a first electronic component 31G has a plurality of first component terminals 311, and a second electronic component 32 having a plurality of second component terminals 321 is arranged on a fourth main surface 122G. One of adjacent ones of the first component terminals 311 corresponds to a first terminal, and another one corresponds to a second terminal. Further, one of adjacent ones of the second electronic component terminals corresponds to a third terminal, and another one corresponds to a fourth terminal.

Each of the first component terminals 311 is electrically connected to a first substrate side wiring 21G. The first component terminal 311 corresponding to the first terminal is electrically connected to the first substrate side wiring 21G corresponding to the first wiring, and the first component terminal 311 corresponding to the second terminal is electrically connected to the first substrate side wiring 21G corresponding to the second wiring.

The second electronic component 32 includes, for example, a connector, an element, and a control circuit.

The second electronic component 32 is arranged on the fourth main surface 122G.

Each of the second component terminals 321 is electrically connected to a second substrate side wiring 22G. The second component terminal 321 corresponding to the third terminal is electrically connected to the second substrate side wiring 22G corresponding to the third wiring, and a second component terminal 322 corresponding to the fourth terminal is electrically connected to the second substrate side wiring 22G corresponding to the fourth wiring.

Then, the shortest distance d3 between adjacent ones of the first component terminals is shorter than a shortest distance d4 between adjacent ones of the second component terminals. That is, an electronic component provided on the first substrate has a narrower distance between terminals than an electronic component provided on the second component. By the above, in a case where the second electronic component is also provided on the second substrate that is stretchable, a shortest distance between the first terminal and the second terminal in the first electronic component on the first substrate is shorter than a shortest distance between the third terminal and the fourth terminal in the second electronic component on the second substrate, so that wirings are relatively sparsely distributed in the second substrate, and degree of manufacturing difficulty can be easily lowered.

In FIG. 13, each of the first component terminal 311 and the second component terminal 321 is arranged on a side surface of an electronic component, but the present disclosure is not limited to this, and each of the first component terminal 311 and the second component terminal 321 may be arranged on a bottom surface of an electronic component. Since an effect of the other configurations are the same as that of the first embodiment, description of the effect will be omitted.

### Ninth Embodiment

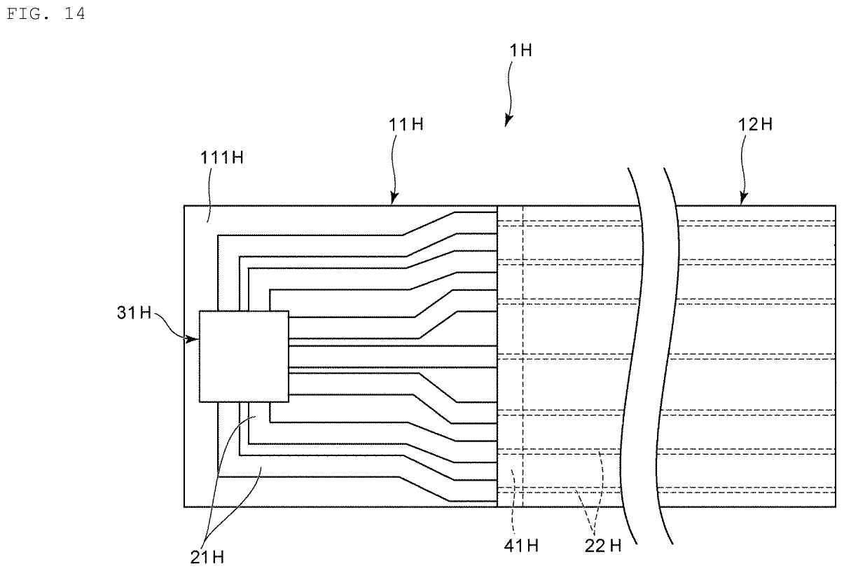

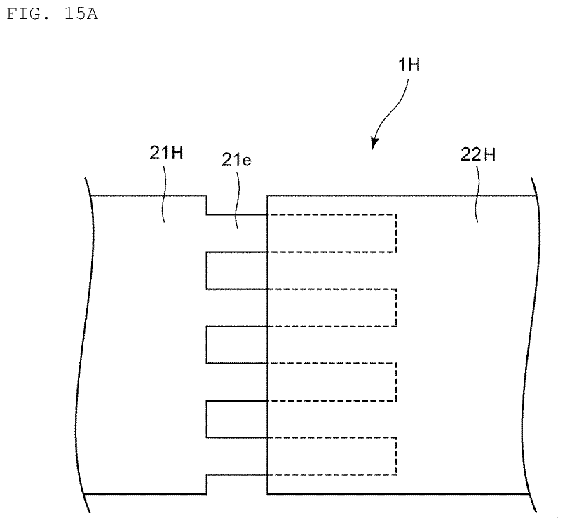

FIG. 14 is a plan view illustrating a ninth embodiment of the stretchable device. The ninth embodiment is different from the first embodiment in a configuration in which width of the first substrate side wiring is wider than width of the second substrate side wiring. This different process will be described below. The other configurations are the same as those of the first embodiment, are denoted by the same reference symbols as those of the first embodiment, and will be omitted from description.

As illustrated in FIG. 14, in a stretchable device 1H of the ninth embodiment, width of a first substrate side wiring 21H is wider than width of a second substrate side wiring 22H. Since width of the first substrate side wiring 21H is wide, deformation of a substrate can be prevented, and connection reliability can be enhanced.

Thickness of the second substrate side wiring 22H is preferably 100 μm or less, more preferably 50 μm or less, and preferably 1 μm or more, more preferably 10 μm or more. The thinner the thickness of the first substrate side wiring 21H, the smaller the unevenness and the easier the lamination and the like. Width of the first substrate side wiring 21H is preferably 100 μm to 10,000 μm, and more preferably 300 μm to 4,000 μm.

In FIG. 14, an end edge of an end portion of the first substrate side wiring 21H and the second substrate side wiring 22H are linear, but the present disclosure is not limited to this. For example, as in the third embodiment, at least one of the first substrate side wiring 21H and the second substrate side wiring 22H may have a comb-tooth-shaped end portion, and preferably, the first substrate side wiring 21H may have a comb-tooth-shaped end portion. By the above, when the first substrate side wiring 21H and the second substrate side wiring 22H are electrically connected via a conductive member (not illustrated), the conductive member can flow out between comb teeth and is not confined between the first substrate side wiring 21H and a second substrate side wiring 22H so that doming is prevented and electrical connection between the first substrate side wiring 21H and the second substrate side wiring 22H becomes excellent.

A comb-tooth-shaped end portion has a plurality of tooth portions 21e provided in parallel and separately in the width direction, and an interval between two adjacent ones of the tooth portions 21e is preferably 700 μm or less for all the tooth portions 21e. As a result, an area of a portion where a first substrate side wiring 21I and the second substrate side wiring 22I overlap is increased, so that the first substrate side wiring 21I and the second substrate side wiring 22I are more reliably electrically connected. Further, an interval between two adjacent ones of the tooth portions 21e is preferably 200 μm or more for all the tooth portions 21e. By the above, a doming prevention effect is more reliably exhibited, and electrical connection between the first substrate side wiring 21I and the second substrate side wiring 22I is further improved. Further, an interval between two adjacent ones of the tooth portions 21e is the same for all the tooth portions. By the above, since a plurality of tooth portions are arranged at equal intervals in the width direction, the first wiring and the third wiring are more reliably electrically connected.

Further, an interval between two adjacent ones of the tooth portions 21e may be 0.5 to 2 times or 0.8 to 1.2 times the width of the tooth portion.

Only at least a part of the tooth portion 21e needs to overlap the second substrate side wiring 22H, and all the tooth portions 21e may overlap the second substrate side wiring 22H.

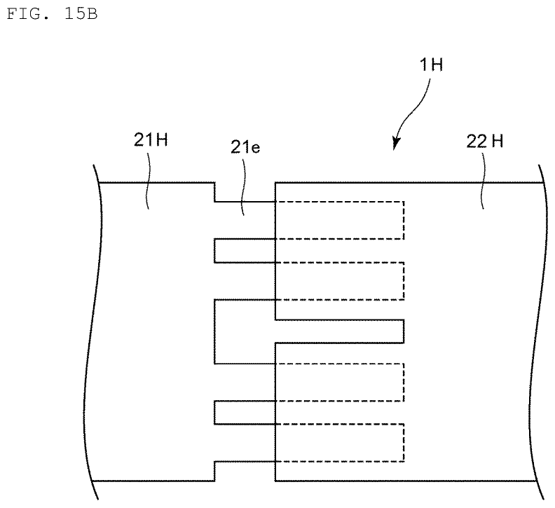

In FIG. 15A, the first substrate side wiring 21H has a comb-tooth-shaped end portion, but the present disclosure is not limited to this, and the second substrate side wiring 22H may have a comb-tooth-shaped end portion on the side connected to the first substrate side wiring 21H. In this case, the number of tooth portions provided at an end portion of the first substrate side wiring 21H and the number of tooth portions provided at an end portion connected to the first substrate side wiring of the second substrate side wiring 22H may be the same or different. The number of tooth portions provided at an end portion of the first substrate side wiring 21H may be twice the number of tooth portions provided at an end portion connected to the first substrate side wiring 21H of the second substrate side wiring 22H. For example, as illustrated in FIG. 15B, the number of tooth portions provided at an end portion of the first substrate side wiring 21H may be four, and the number of tooth portions provided at an end portion connected to the first substrate side wiring 21H of the second substrate side wiring 22H may be two. The number of tooth portions provided at an end portion of the first substrate side wiring 21H may be ½ times the number of tooth portions provided at an end portion connected to the first substrate side wiring 21H of the second substrate side wiring 22H. Furthermore, the number of tooth portions provided at an end portion of the first substrate side wiring 21H may be two, and the number of tooth portions provided at an end portion connected to the first substrate side wiring 21H of the second substrate side wiring 22H may be four. Further, in FIG. 15B, the number of tooth portions provided at a comb-tooth-shaped end portion is two or four, but the present disclosure is not limited to this, and the number can be freely increased or decreased. Since an effect of the other configurations are the same as that of the first embodiment, description of the effect will be omitted.

Note that the present disclosure is not limited to the above-described embodiment, and can be changed in design without departing from the gist of the present disclosure. For example, feature points of the first to ninth embodiments may be combined in various ways.

In the first embodiment, width of the first substrate side wiring is narrower than width of the second substrate side wiring, and in the ninth embodiment, width of the first substrate side wiring is wider than width of the second substrate side wiring, but the present disclosure is not limited to this. For example, the first substrate side wirings may include a wiring having width wider than that of the second substrate side wiring and a wiring having width narrower than that of the second substrate side wiring. Further, width of the first substrate side wiring and width of the second substrate side wiring may be the same.

In the above embodiment, the first substrate has a rectangular shape, but is not limited to a rectangular shape, and may have, for example, a polygonal shape. The polygonal shape may be a polygonal shape protruding outward, or may be a polygonal shape recessed inward.

In the above embodiment, the second substrate has a rectangular shape, but is not limited to a rectangular shape, and may have a non-long shape such as a polygon, a circle, or an ellipse.

In the above embodiment, the third substrate has a rectangular shape, but is not limited to a rectangular shape, and may have, for example, a polygonal shape. The polygonal shape may be a polygonal shape protruding outward, or may be a polygonal shape recessed inward.

In the above embodiment, the first electronic component is arranged on the first main surface, but may be arranged on the second main surface, for example, without limitation to the first main surface.

In the above embodiment, the second electronic component is arranged on the fourth main surface, but may be arranged on the third main surface without limitation to the fourth main surface.

### DESCRIPTION OF REFERENCE SYMBOLS

1, 1A to 1H: Stretchable device
11, 11C to 11H: First substrate
111, 111C to 111H: First main surface
112, 112C to 112H: Second main surface
11a: Edge side
12, 12A to 12H: Second substrate
121, 121E, 121F: Third main surface
122, 122E, 122F: Fourth main surface
12a, 12b: Edge side
13: Third substrate
131: Fifth main surface
132: Sixth main surface
13a: Edge side
21, 21a, 21b, 21c, 21d, 21A to 21H: First substrate side wiring
22, 22a, 22b, 22c, 22d, 22A to 22H: Second substrate side wiring
21e, 22a: Tooth portion
23, 23a, 23b, 23c, 23d: Third substrate side wiring
27: Fifth wiring
31, 31G to 31H: First electronic component
311: First substrate side component terminal
32: Second electronic component
321: Second substrate side component terminal
33: Third electronic component
41, 41A to 41H: Conductive member
411: Conductive particle
42: Mounting electrode
43: Solder
44: First connector
45: Second connector
51, 51C, 51D: First insulating coating layer
52, 52D: Second insulating coating layer
53: First insulating member
54: Second insulating member

1. A stretchable device comprising:
a first substrate having a first main surface and a second main surface facing each other;
a first wiring on the first main surface and extending along the first main surface;
a second wiring adjacent to the first wiring;
a second stretchable substrate having a third main surface and a fourth main surface facing each other, the second stretchable substrate connected to the first stretchable substrate;
a stretchable third wiring on the fourth main surface and extending along the fourth main surface; and
a stretchable fourth wiring adjacent to the third wiring, wherein
a shortest distance between the first wiring and the second wiring is shorter than a shortest distance between the third wiring and the fourth wiring.

2. The stretchable device according to claim 1, wherein
the shortest distance between the first wiring and the second wiring is less than 250 μm, and
the shortest distance between the third wiring and the fourth wiring is 250 μm or more.

3. The stretchable device according to claim 1, further comprising a first electronic component only on the first main surface and electrically connected to the first wiring and the second wiring.

4. The stretchable device according to claim 1, further comprising:
a first electronic component on the first main surface; and
a second electronic component on the fourth main surface, wherein
the first electronic component includes a first terminal electrically connected to the first wiring and a second terminal electrically connected to the second wiring,
the second electronic component includes a third terminal electrically connected to the third wiring and a fourth terminal electrically connected to the fourth wiring, and
a shortest distance between the first terminal and the second terminal is shorter than a shortest distance between the third terminal and the fourth terminal.

5. The stretchable device according to claim 1, further comprising a fifth wiring on the first main surface, wherein
the fifth wiring has a region overlapping the first wiring or the second wiring when viewed from a direction orthogonal to the first main surface.

6. The stretchable device according to claim 1, further comprising a conductive member electrically connecting the first wiring and the third wiring.

7. The stretchable device according to claim 6, wherein
the first substrate and the second substrate are arranged such that the first main surface and the fourth main surface face each other,
the first wiring and the third wiring are arranged to face each other in the direction orthogonal to the first main surface, and
the conductive member is arranged between the first wiring and the third wiring.

8. The stretchable device according to claim 6, wherein
the conductive member contains a conductive particle, and
particle size of the conductive particle is larger than a distance between the first wiring and the third wiring.

9. The stretchable device according to claim 6, wherein
in a first section orthogonal to a direction in which the first wiring extends in a region where the conductive member, the first wiring, and the third wiring overlap,
a width of the first wiring and a width of the third wiring are different.

10. The stretchable device according to claim 9, wherein
in a second section orthogonal to a direction in which the first wiring extends in a portion where the first wiring and the third wiring overlap,
a width of a narrower one of the first wiring and the third wiring is 500 μm or less.

11. The stretchable device according to claim 6, wherein an end portion of at least one of the first wiring and the third wiring has a plurality of tooth portions in parallel and separated in a width direction.

12. The stretchable device according to claim 11, wherein a distance between two adjacent tooth portions of the plurality of tooth portions is 700 μm or less.

13. The stretchable device according to claim 11, wherein distances between two adjacent tooth portions of the plurality of tooth portions are all the same.

14. The stretchable device according to claim 11, wherein a distance between two adjacent tooth portions of the plurality of tooth portions is 200 μm or more.

15. The stretchable device according to claim 1, further comprising a first insulating coating layer coating the first wiring and overlapping the conductive member when viewed from a direction orthogonal to the first main surface.

16. The stretchable device according to claim 1, further comprising a second insulating coating layer coating the second wiring and overlapping the conductive member when viewed from a direction orthogonal to the fourth main surface.

17. The stretchable device according to claim 1, wherein the first substrate is stretchable.

18. The stretchable device according to claim 1, wherein the first wiring and the second wiring are stretchable.

19. The stretchable device according to claim 1, further comprising:
a third substrate having a fifth main surface and a sixth main surface facing each other; and
a sixth wiring and a seventh wiring on the fifth main surface and extending along the fifth main surface, wherein
the second substrate and the third substrate are connected, and
a shortest distance between the sixth wiring and the seventh wiring is shorter than a shortest distance between the third wiring and the fourth wiring.
